(19) United States
(12) Patent Application Publication
(10) Pub. No.: US 2015/0136644 A1
(43) Pub. Date: May 21, 2015

(54) Mobile Device Holder with Pliable Extension Arms

(71) Applicant: Marc Robert Major, Los Angeles, CA (US)

(72) Inventor: Marc Robert Major, Los Angeles, CA (US)

(21) Appl. No.: 14/081,768

(22) Filed: Nov. 15, 2013

(51) Int. Cl. B65D 25/20; H05K 5/00; B65D 51/00; H05K 5/02

(52) U.S. Cl. CPC B65D 25/20; H05K 5/02; H05K 5/0017; H05K 5/0086; B65D 51/00
USPC 206/736

(57) ABSTRACT

Mobile device holders and related methods are discussed herein. Some embodiments may provide for a mobile device holder including a body portion and one or semi-rigid multifunction supports. The one or more semi-rigid multifunction supports may be attached to the body portion and may be pliably shaped into various configurations such the extension arms are capable of supporting the weight of the mobile device holder, thereby allowing the mobile device holder to be mounted or otherwise stationed in a wide variety of environments.

### FIELD

Embodiments of the invention relate, generally, to mobile device holders with extension arms and related methods.

### BACKGROUND

Mobile devices, such as tablets, allow users to perform tasks on the move. The exterior casing of mobile devices, as well as conventional mobile device holders (e.g., cases, covers, protective screens, etc.), are typically designed for mobile devices to be held in the user's hands or placed on a flat surface (e.g., with the mobile device flat on the surface or standing at an angle to the surface). However, such designs limit the type of user interactions or activities that are possible with mobile devices. In this regard, improved mobile device or holders are desirable.

### BRIEF SUMMARY

Through applied effort, ingenuity, and innovation, solutions to improve such mobile device holders have been realized and are described herein. For example, mobile device holders and related methods are described herein. Some embodiments may provide for a mobile device holder including one or more (e.g., two) semi-rigid multifunction supports and/or extension arms. The semi-rigid multifunction supports may be attached with a frame and/or body portion that includes a mobile device receiving area within the interior of the body portion. As discussed in further detail herein, a semi-rigid multifunction support can be pliably shaped into various configurations capable of supporting the weight of the mobile device holder (e.g., with or without a mobile device being inserted within an interior of a body portion of the mobile device holder). As such, the mobile device holder allows the mobile device to be mounted (e.g., clamped, hung, etc.) to an object or otherwise stationed in variable environments via the user shaping the extension arms into the various configurations.

In some embodiments, at least a portion of the semi-rigid multifunction support includes a pliably rigid core surrounded by an elastic cladding. The pliably rigid core may include a metallic material.

In some embodiments, the frame may include an opening that defines a mobile device display access region and a mobile device camera access region.

In some embodiments, the frame may include: a front surface defining a mobile device display access region; and a back surface opposite the front surface. The semi-rigid multifunction support is rotatably mounted to the back surface of the frame.

In some embodiments, the semi-rigid multifunction support may include a joint portion and a hand portion. The semi-rigid multifunction support may be rotatably mounted to the frame at the joint portion. The frame may further include a pocket mounted to the back surface. The pocket may be configured to securely hold the semi-rigid multifunction support when the hand portion of the semi-rigid multifunction support is received by the pocket. In some embodiments, the frame may further include a pocket configured to securely hold the semi-rigid multifunction support against a surface of the frame.

In some embodiments, the semi-rigid multifunction support is rotatably mounted to the frame via a bolt.

In some embodiments, the semi-rigid multifunction support may include a joint portion and a hand portion; the semi-rigid multifunction support may be rotatably mounted to the frame at the joint portion; and the semi-rigid multifunction support may include one or more flexible fingers at the hand portion.

In some embodiments, the frame may further define one or more connector access regions to provide access to one or more connectors of a mobile device when the mobile device is located within the mobile device receiving area. For example, the one or more connector access regions may include a connector access region for one of a power connector, a data connector, and a power and data connector.

In some embodiments, the frame may further define one or more button access regions to provide access to one or more buttons of the mobile device when the mobile device is located within the mobile device receiving area. For example, the one or more button access regions may include a button access region for one of an on/off button, a sleep/wake button, a volume button, a mute button, a display screen rotation lock button, and a home button. In some embodiments, the frame may further define one or more of a microphone access region, a speaker access region, and a camera access region. In some embodiments, the frame may further define a handle for the mobile device holder.

Some embodiments may provide for a mobile device holder including a body portion, a first extension arm, and a second extension arm. The body portion may include: a mobile device receiving area within an interior of the body portion; a front surface defining a mobile device display window; and a back surface opposite the front surface. The first extension arm may be attached to the back surface of the body portion. The second extension arm may be attached to the back surface of the body portion. The first extension arm and the second extension arm may be rotatably mounted to the body portion. The first extension arm and the second extension arm can each be pliably shaped into various configurations such that first extension arm and the second extension may be capable of supporting the weight of the mobile device holder.

Some embodiments may provide for a method for securely holding a mobile device with a mobile device holder. The method may include: inserting the mobile device into a mobile device holder, wherein the mobile device holder includes an extension arm that can be pliably shaped into various configurations capable of supporting the weight of the mobile device holder; shaping the extension arm into a configuration; and supporting at least a portion of the weight of the mobile device holder with the extension arm in the configuration.

In some embodiments, supporting at least the portion of the weight of the mobile device holder with the extension arm in the configuration may include bending the extension arm around at least a portion of an object. In some embodiments, supporting at least the portion of the weight of the mobile device holder with the extension arm in the configuration may include standing the mobile device holder on a surface. In some embodiments, the method may further include securely holding the extension arm against a body portion of the mobile holder device.

These characteristics as well as additional features, functions, and details of various embodiments are described below. Similarly, corresponding and additional embodiments are also described below.

### BRIEF DESCRIPTION OF THE DRAWINGS

Having thus described some embodiments in general terms, reference will now be made to the accompanying drawings, which are not necessarily drawn to scale, and wherein:

FIG. 1 shows a front view of a mobile device holder, in accordance with some embodiments;

FIG. 2 shows a back view of the mobile device holder, in accordance with some embodiments;

FIG. 3 shows a back view of the mobile device holder, in accordance with some embodiments;

FIG. 4 shows a bottom view of the mobile device holder, in accordance with some embodiments;

FIG. 5 shows a left side view of the mobile device holder, in accordance with some embodiments;

FIG. 6 shows a right side view of the mobile device holder, in accordance with some embodiments;

FIG. 7 shows a flowchart of an example method for securely holding a mobile device, in accordance with some embodiments;

FIG. 8 shows a mobile device holder mounted to an exercise machine, in accordance with some embodiments;

FIG. 9 shows a mobile device holder standing on a surface, in accordance with some embodiments;

FIG. 10 shows a front view of a mobile device holder, in accordance with some embodiments; and

FIG. 11 shows a back view of a mobile device holder, in accordance with some embodiments.

### DETAILED DESCRIPTION

Embodiments will be described more fully hereinafter with reference to the accompanying drawings, in which some, but not all embodiments contemplated herein are shown. Indeed, various embodiments may be implemented in many different forms and should not be construed as limited to the embodiments set forth herein; rather, these embodiments are provided so that this disclosure will satisfy applicable legal requirements. Like numbers refer to like elements throughout.

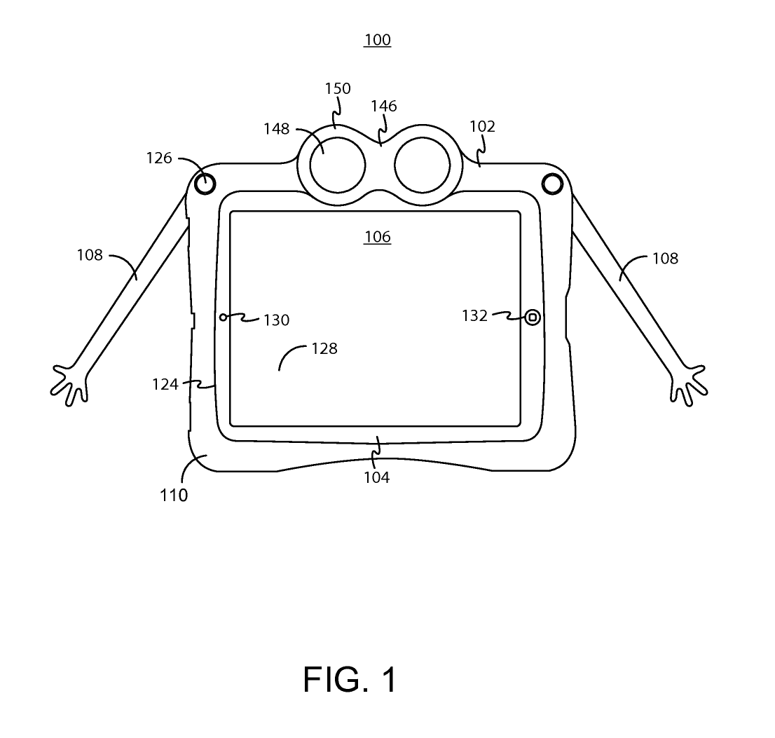

FIGS. 1-6 show various views of an example media holder 100, in accordance with some embodiments. With reference to FIG. 1, showing a front view, media holder 100 may include a frame or body portion 102. Body portion 102 may be shaped to hold a mobile device, such as mobile device 106 which is shown in FIGS. 1-6 as a tablet. In various embodiments, media holder 100 may be dimensioned in accordance with the size and/or shape of various mobile devices including but not limited to tablets, mobile phones, smart phones, laptops, among other things.

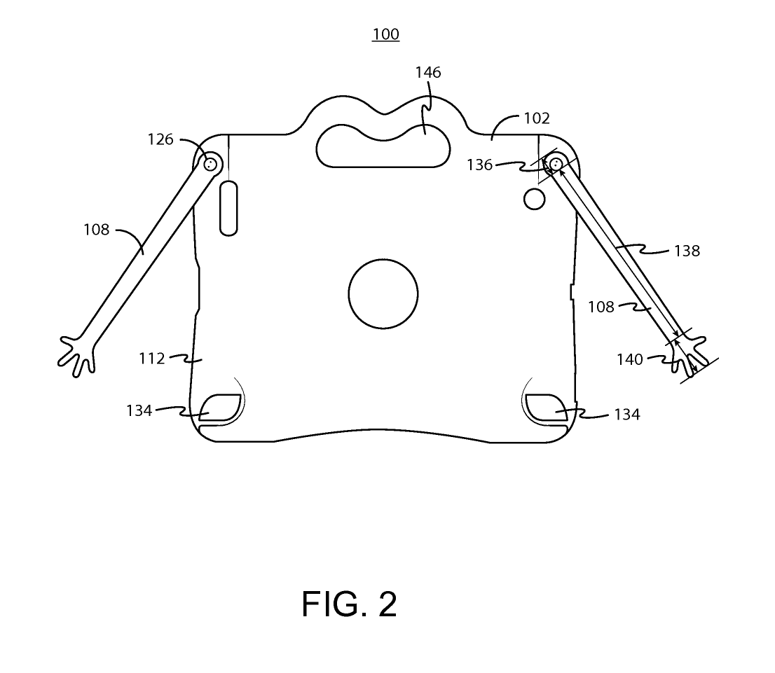

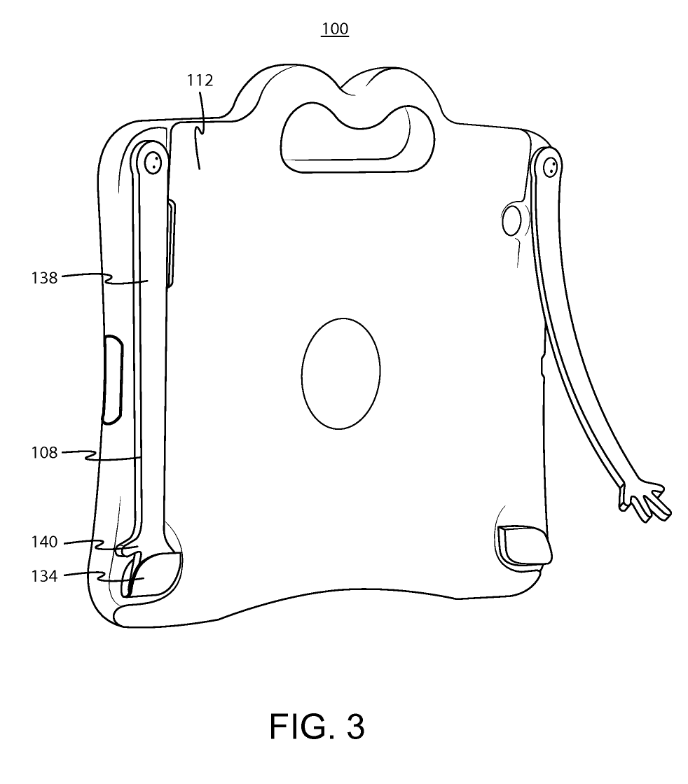

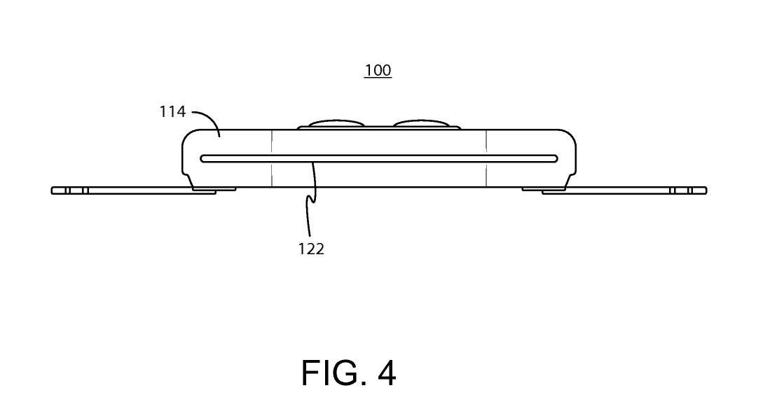

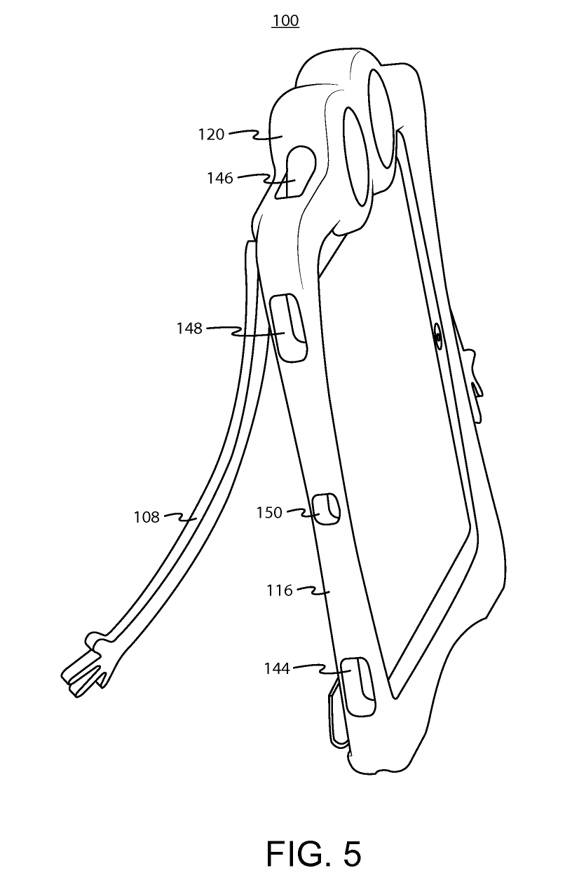

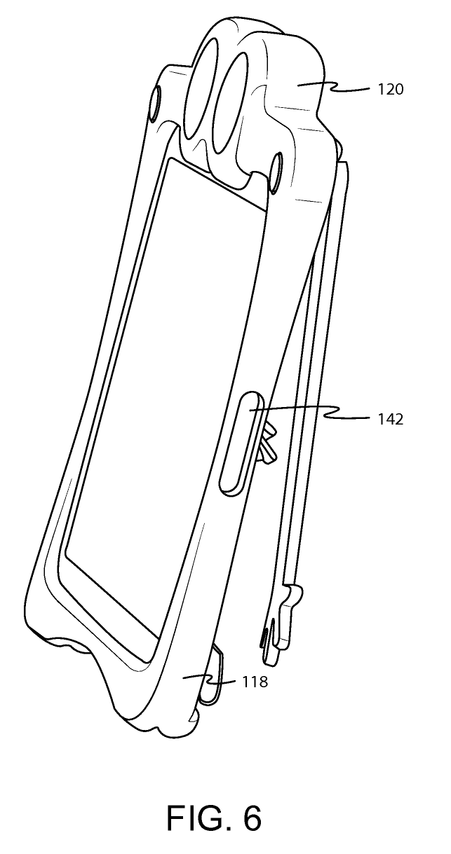

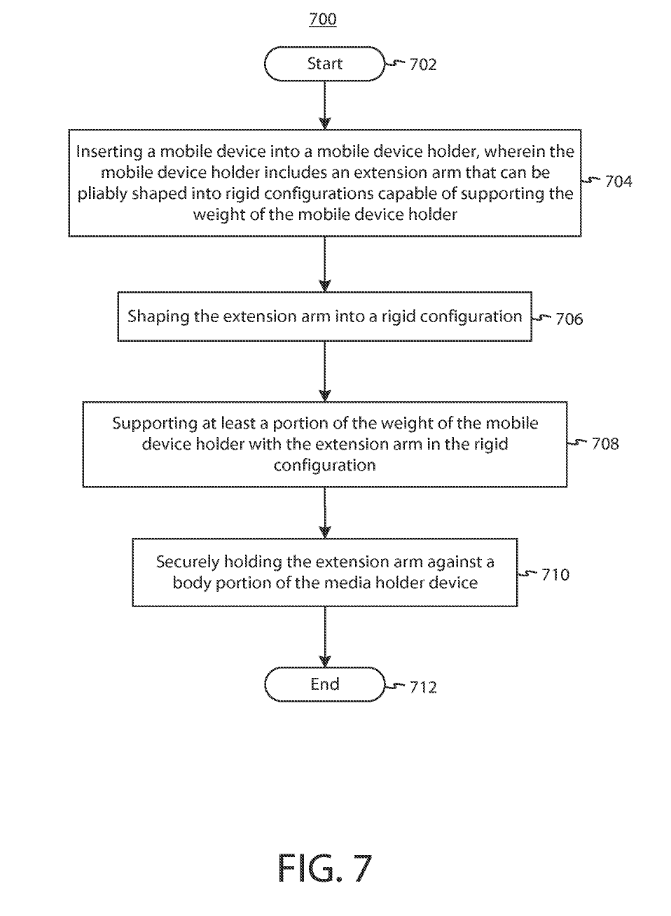

In some embodiments, body portion 102 may include front surface 110 (e.g., as shown in FIG. 1), back surface 112 (e.g., as shown in FIGS. 2 and 3), bottom surface 114 (e.g., as shown in FIG. 4), left surface 116 (e.g., as shown in FIG. 5), right surface 118 (e.g., as shown in FIG. 6) and top surface 120 (e.g., as shown in FIGS. 6 and 7. Here, the directions “top,” “bottom,” “left,” and “right” are referenced from the perspective of a user viewing mobile device holder 100 from the perspective shown in FIG. 1.

In some embodiments, body portion 102 may be made of elastic material such as thermoplastic polyurethane (TPU) that is rugged, lightweight, water-resistant, and/or substantially inactive with respect to wireless signal interference. Other suitable materials may be used. In some embodiments, the elastic material of body portion 102 may be dimensioned such that the elastic material is slightly stretched when mobile device 106 is inserted within body portion 102 to provide for the secure holding of mobile device 106 to body portion 102. In various other embodiments, some or all of body portion 102 may be made of an inelastic material, such as a metal or inelastic plastic.

In some embodiments, body portion 102 may include an interior defining a mobile device receiving area 104 within which mobile device 106 may be inserted. For example and with reference to FIG. 4, showing a bottom view of mobile device holder 100, body portion 102 may include a mobile device insertion slot 122 for receiving the mobile device. In some embodiments, mobile device insertion slot 122 may be of a (e.g., elastic) material and/or construction such that mobile device insertion slot 122 may securely hold mobile device 106 within body portion 102 and may also be flexed open by a user for insertion and/or removal of mobile device 106. Alternatively or additionally, body portion 102 may include one or more securing elements for securing mobile device 106, such as one or more magnets, adhesives, locks, and/or clamps. In that sense, mobile device 106 may be secured to mobile device holder 100 using any suitable technique including physical and/or electromagnetic means.

In some embodiments and with reference to FIG. 1, front surface 114 of body portion 102 may define mobile device display window 124. Mobile device display window 124 may be defined by an opened portion of front surface 114 to provide visual and/or touch access to display 128 of mobile device 106. In some embodiments, mobile device display window 124 may further include a screen or other protective cover. In some embodiments, mobile device display window 124 may be defined by an opened portion of front surface 114 that is sufficiently large to also allow user access to one or more front facing features of mobile device 106. For example, mobile device display window 124 may include a mobile device display access region for access to display 128, a mobile device camera access region for access to camera 130, and/or button access region for access to home button 132.

Mobile holder 100 may further include one or more semi-rigid multifunction supports attached to body portion 102. In some embodiments, a semi-rigid multifunction support may include an extension arm 108. In some embodiments, an extension arm 108 may be pliable such that a user can freely bend, twist, straighten, among other things, one or more portions of extension arm 108. When shaped into a configuration (e.g., extended straight, bent into an elbow, wrapped around an object, etc.), extension arms 108 may remain in the configuration, such as until sufficient force is applied to change the configuration. In some embodiments, extension arm 108 may be of a material and/or construction such that extension arm 108 can be reshaped by force comfortably generated by a user's hands and remain sufficiently rigid to support the weight of media holder 100 when mobile device 106 is contained therein. In that sense, an extension arm 108 can be pliably shaped into various configurations capable of supporting the weight of the mobile device holder (e.g., individually and/or collectively with one or more other extension arms).

In some embodiments and with reference to FIG. 2, extension arm 108 may include one or more portions such as joint portion 136, arm portion 138, and hand portion 140. Extension arm 108 may be attached with body portion 102 via joint portion 136. In some embodiments, some (e.g., at least arm portion 138) or all portions of extension arm 108 may include a pliably rigid core surrounded by an elastic cladding that defines the exterior of extension arm 108. For example, the pliably rigid core may include a metallic material. The elastic cladding may include a flexible polymer material. In some embodiments, hand portion 140 may include one or more flexible fingers for enhanced elastic gripping of objects. In various embodiments, the one or more flexible fingers may include a pliably rigid core or may include only elastic material. Hand portion 140 is not necessarily limited to hand or finger-like features. For example, in some embodiments, hand portion 140 may include suctions, weighting materials, adhesive materials, locking mechanisms (e.g., to connect two hand portions 140), etc.

In some embodiments, extension arms 108 may be rotatably mounted to body portion 102. FIG. 2 shows a back view of the mobile device holder, in accordance with some embodiments. Here, extension arms 108 are shown as being rotatably mounted to body portion 102 via bolt 124 such that extension arms 108 may each rotate about a rotation axis that is perpendicular to the surface of body portion 102 at which extension arms 108 are mounted. In some embodiments, extension arm 108 may be rotatably mounted to back surface 112 such that extension arm 108 may rotate relative to back surface 112 and/or bolt 124. In various other embodiments, one or more extension arms 108 may be mounted (e.g., rotatably or otherwise) to body portion 102, such as at back surface 112 and/or a different surface.

In some embodiments, body portion 102 may further include one or more pockets for securing extension arms 108, such as when extension arms 108 are not actively in use (e.g., when mobile device holder 100 is being held by the user or otherwise carried on the user's person). With reference to FIGS. 2 and 3, showing back views of mobile device holder 100, body portion 102 may include one or more pockets 134 configured to each securely hold an extension arm 108. For example, mobile device holder may include a pocket 134 for each extension arm 108 attached to body portion 102.

In some embodiments, pocket 134 may be configured to securely hold an extension arm 108 against body portion 102. For example, where an extension arm 108 is mounted to a particular surface (e.g., back surface 112), a corresponding pocket 134 may also be mounted to the surface such that extension arm 108 can be securely held against the surface of body portion 102. As shown in FIG. 3, for example, extension arm 108 may be securely held against back surface 112 when hand portion 140 of extension arm 108 is placed within pocket 134. In some embodiments, body portion 102 may alternatively or additionally include one or more other extension arm securing elements for securing extension arm 108, such as one or more magnets, adhesives, locks, and/or clamps. In that sense, extension arm 108 may be secured to mobile device holder 100 using any suitable technique including physical and/or electromagnetic means.

In some embodiments, body portion 102 of mobile device holder 100 may define one or more access regions. The access regions may be defined by openings in body portion 102 that allow access to various features (e.g., input/output interfaces) of mobile device 106 when mobile device 106 is located in mobile device receiving area 104. In that sense, the locations of access regions discussed herein are only example locations suitable for mobile device 106 and may vary in accordance with mobile device designs. Some example access regions may include a connector access region, a button access region, a microphone access region, a speaker access region, and/or a camera access region.

A connector access region may provide access to one or more connectors of mobile device 106 when mobile device 106 is located within mobile device receiving area 104. For example, body portion 102 may define one or more connector access regions such as a connector access region a power connector, a data connector, and/or a power and data connector (e.g., a pin connector, Universal Serial Bus (USB) connector, audio jack connector, Ethernet connector, among other things). With reference to FIG. 6, showing a right side view of mobile device holder 100, right surface 118 of body portion 102 may define connector access region 142 to allow access to a power and data connector of mobile device 106. In another example shown in FIG. 5, showing a left side view of mobile device holder 100, left surface 116 of body portion 102 may define connector access region 144 to allow access to an audio jack connector of mobile device 106.

A button access region may provide access to one or more buttons of mobile device 106 when mobile device 106 is located within mobile device receiving area 104. For example, body portion 102 may define one or more button access regions such as for an on/off button, a sleep/wake button, a volume button, a mute button, a display screen rotation lock button, and/or a home button. With reference to FIG. 5, top surface 120 may of body portion 102 may define button access region 146 to allow access to a volume button, mute button, and/or display screen rotation lock button, among other things. Left surface 116 may define button access region 148 configured to allow access to an on/off button and/or a sleep/wake button, among other things.

Some other example access regions of body portion 102 may include microphone access region 150, a speaker access region (e.g., shown in FIG. 6 as part of connector access region 142), and a camera access region (e.g., shown in FIG. 1 as part of mobile device display window 124, but may be separate, such as when the camera of mobile device 106 is located in another location like the back surface of mobile device 106). In that sense, a single access region may provide access to one or more (e.g., different) input/output features of mobile device 106.

In some embodiments, mobile device holder 100 may further include a handle. For example, the handle may allow a user to hold mobile device holder 100 comfortably in one hand when mobile device holder 100 is being transported. For example and with reference to FIG. 2, body portion 102 may define handle 146, here formed of a concave portion of back surface 112. As shown in FIG. 1, handle 146 may be disguised with an aesthetic design such as eye attachments 148 within sockets 150. In some embodiments, varieties of eye attachments 148 with different designs (e.g., happy, winking, sleeping, or angry eyes) may be removably attached to body portion 102 via Velcro, magnets, mechanical coupling, or any other suitably technique.

FIG. 7 shows a flowchart of an example method for securely holding a mobile device, in accordance with some embodiments. Method 700 may be performed with a mobile device holder, such as the mobile device holders discussed herein.

Method 700 may begin at 702 and proceed to 704, where a mobile device may be inserted into a mobile device holder. For example, the mobile device holder may include an (e.g., one or more) extension arm that can be pliably shaped into various and/or semi-rigid configurations that are capable of supporting the weight of the mobile device holder (e.g., in the course of use as discussed in further detail below).

At 706, the extension arm(s) of the mobile device holder may be shaped into a configuration. As discussed above, extension arms 108 of mobile device holder 100 may reshaped by force comfortably generated by a user's hands and remain sufficiently rigid to support the weight of media holder 100 when mobile device 106 is contained therein.

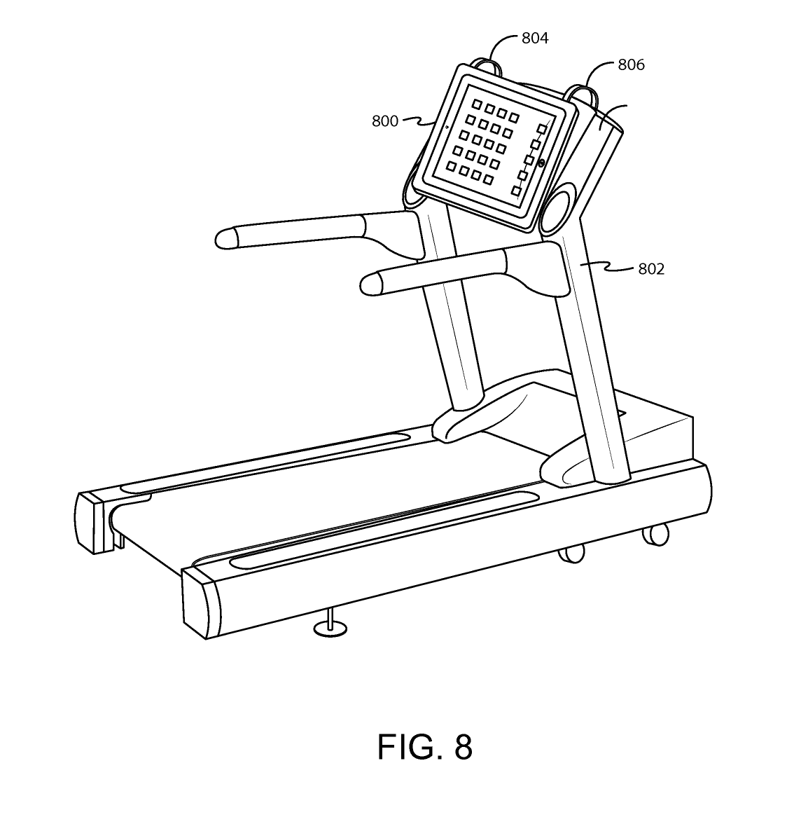

At 706, at least a portion of the weight of the mobile device holder may be supported with the extension arm in the configuration. FIG. 8 shows a mobile device holder 800 mounted to an exercise machine 802, in accordance with some embodiments. Extension arms 804 and 806 may be bent into the configuration shown such that extension arms 804 and 806 wrap over the top of panel/monitor 808 of exercise machine 802 to support the weight of mobile device holder 800 and/or keep mobile device holder 800 held securely in place. As such, supporting at least the portion of the weight of the mobile device holder with the extension arm in the configuration may include bending the extension arm around at least a portion of an object, such as the top/back of panel/monitor 808 as shown for extension arms 804 and 806.

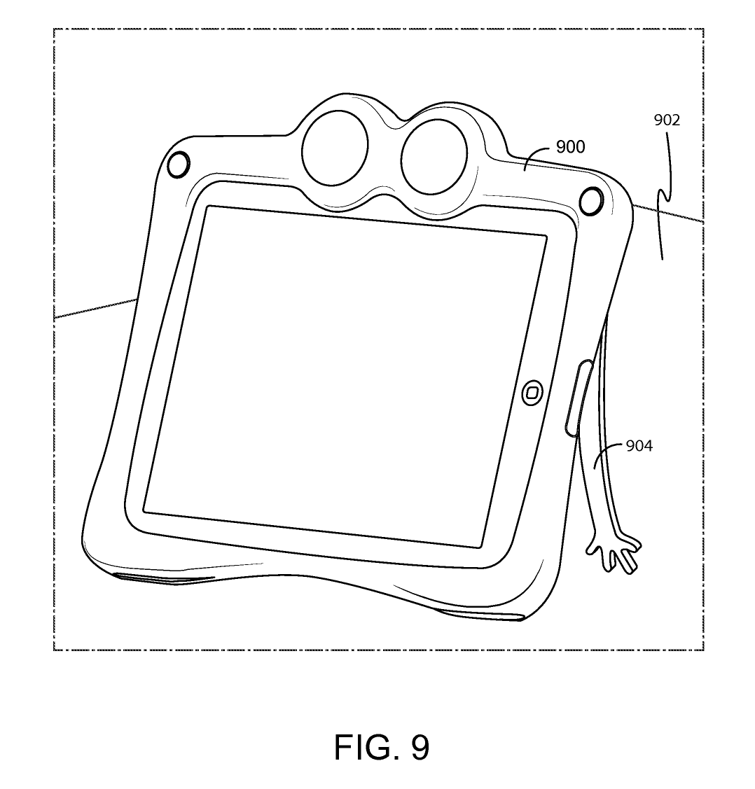

In another example, supporting at least the portion of the weight of the mobile device holder with the extension arm in the configuration may include standing the mobile device holder on a surface. FIG. 9 shows a mobile device holder 900 standing on a surface 902, in accordance with some embodiments. Here, extension arm 904 may support at least a portion of the weight of mobile device holder 900 by keeping mobile device holder balanced in the shown upright position as supported by extension arm 904 (e.g., and a second extension arm that is not visible in the view of FIG. 9). While FIGS. 8 and 9 show two example extension arm configurations for two different environments, it is appreciated that the extension arms can be shaped into virtually any configuration as suitable or desirable for a particular environment.

In some embodiments, a mobile device holder may be used with a mobile device (e.g. held within the mobile device holder) including circuitry configured to provide motion controlled virtual world interaction, such as for an interactive game playable in the course of exercising. For example, the mobile device may be configured to execute a workout mode where the mobile device holder may be mounted to an exercise machine, thereby allowing at least one of the user's hands to interact with a touchscreen of the mobile device in the workout mode. In another example, the mobile device may be configured to execute a standalone mode where the mobile device holder may be held in the user's hands. The mobile device may further include one or more sensors (e.g., camera, accelerometer, gyroscope) that may be used to perform various motion indicator measurements. These measurements may then be programmatically converted to an activity level score that can be used to traverse (e.g., at various speeds that can depend on the activity level score) through the virtual environment provided by the mobile device display. Additional details regarding motion controlled virtual world interaction, applicable to some embodiments, are discussed in U.S. patent application Ser. No. 14/081,735, titled “Systems, Apparatus, and Methods for Motion Controlled Virtual Environment Interaction,” filed Nov. 15, 2013, which is incorporated by reference herein in its entirety.

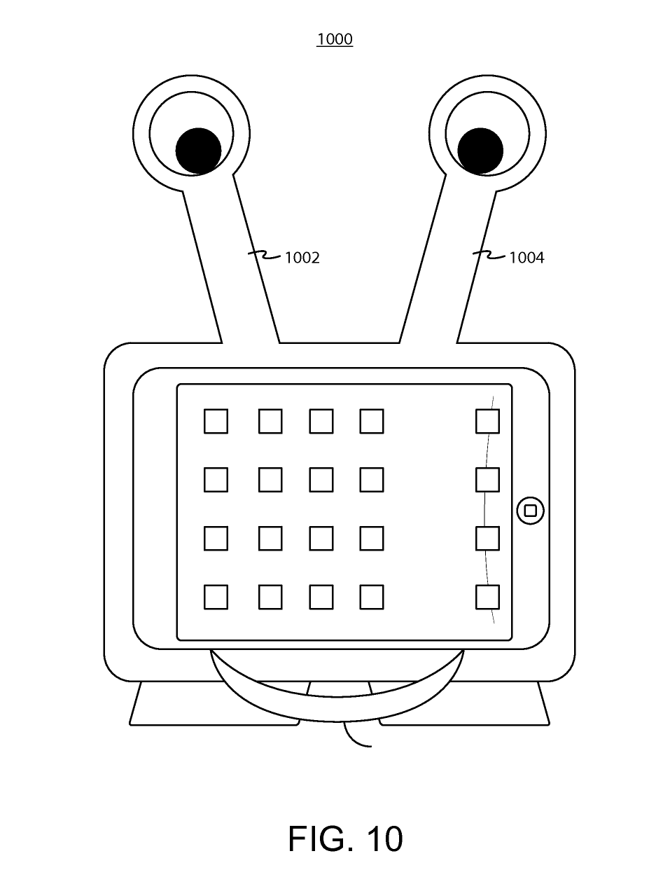

FIG. 10 shows a front view of a mobile device holder 1000, in accordance with some embodiments. Some and/or all of the discussion herein regarding mobile device holder 100 may be applicable to mobile device holder 1000. Here, extension arms 1002 and 1004 may include decorative elements (e.g., the removable or permanently attached eyes shown in FIG. 10) at the hand portions. Mobile device holder 1000 may further include handle 1006, which may also function as a towel holder (e.g., among other things), such as when mobile device holder 1000 is mounted to an exercise machine. Accordingly, the various features of mobile device holders discussed herein are not necessarily located in the locations discussed herein.

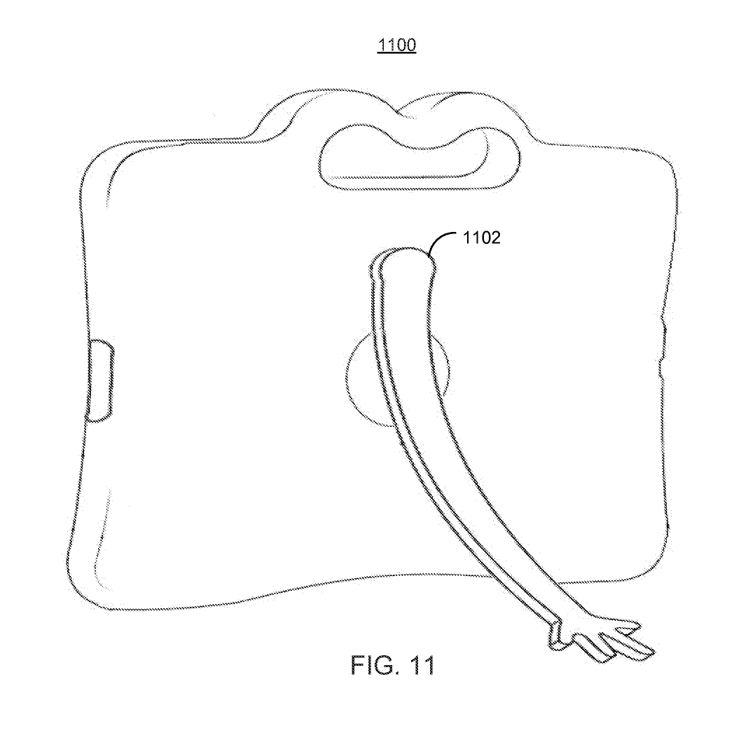

FIG. 11 shows a back view of a mobile device holder 1100, in accordance with some embodiments. In some embodiments, a mobile device holder may include less or more than two semi-rigid multifunction supports and/or extension arms. For example, mobile device holder 1100 includes extension arm 1102, shown here as a larger being larger than extension arms 108. Furthermore, extension arm 1102 is mechanically fixed to the body portion rather than being rotatably mounted. In various embodiments, one or more extension arms may be fixed, rotatably mounted, hinge-mounted, and/or otherwise mechanically attached to a mobile device holder.

Many modifications and other embodiments will come to mind to one skilled in the art to which these embodiments pertain having the benefit of the teachings presented in the foregoing descriptions and the associated drawings. Therefore, it is to be understood that embodiments and implementations are not to be limited to the specific examples disclosed and that modifications and other embodiments are intended to be included within the scope of the appended claims. Although specific terms are employed herein, they are used in a generic and descriptive sense only and not for purposes of limitation.

That which is claimed:

1. A mobile device holder, comprising:
a frame defining a mobile device receiving area within an interior of the frame; and
a semi-rigid multifunction support attached to the body portion, wherein:
the semi-rigid multifunction support is mounted to the body portion; and
the semi-rigid multifunction support can be pliably shaped into various configurations capable of supporting the weight of the mobile device holder.

2. The mobile device holder of claim 1, wherein at least a portion of the semi-rigid multifunction support includes a pliably rigid core surrounded by an elastic cladding.

3. The mobile device holder of claim 2, wherein the pliably rigid core includes a metallic material.

4. The mobile device holder of claim 1, wherein the frame includes an opening that defines a mobile device display access region and a mobile device camera access region.

5. The mobile device holder of claim 1, wherein:
the frame further includes:
a front surface defining a mobile device display access region; and
a back surface opposite the front surface; and
the semi-rigid multifunction support is rotatably mounted to the back surface of the frame.

6. The mobile device holder of claim 5, wherein:
the semi-rigid multifunction support includes a joint portion and a hand portion;
the semi-rigid multifunction support is rotatably mounted to the frame at the joint portion;
the frame further includes a pocket mounted to the back surface; and
the pocket is configured to securely hold the semi-rigid multifunction support when the hand portion of the semi-rigid multifunction support is received by the pocket.

7. The mobile device holder of claim 5, wherein the frame further includes a pocket configured to securely hold the semi-rigid multifunction support against a surface of the frame.

8. The mobile device holder of claim 1, wherein the semi-rigid multifunction support is rotatably mounted to the frame via a bolt.

9. The mobile device holder of claim 1, wherein:
the semi-rigid multifunction support includes a joint portion and a hand portion;
the semi-rigid multifunction support is rotatably mounted to the frame at the joint portion; and
the semi-rigid multifunction support includes one or more flexible fingers at the hand portion.

10. The mobile device holder of claim 1, wherein the frame further defines one or more connector access regions to provide access to one or more connectors of a mobile device when the mobile device is located within the mobile device receiving area.

11. The mobile device holder of claim 10, wherein the one or more connector access regions includes a connector access region for one of a power connector, a data connector, and a power and data connector.

12. The mobile device holder of claim 1, wherein the frame further defines one or more button access regions to provide access to one or more buttons of the mobile device when the mobile device is located within the mobile device receiving area.

13. The mobile device holder of claim 12, wherein the one or more button access regions includes a button access region for one of an on/off button, a sleep/wake button, a volume button, a mute button, a display screen rotation lock button, and a home button.

14. The mobile device holder of claim 1, wherein the frame further defines one or more of a microphone access region, a speaker access region, and a camera access region.

15. The mobile device holder of claim 1, wherein the frame further defines a handle for the mobile device holder.

16. A method for securely holding a mobile device, comprising:
inserting the mobile device into a mobile device holder, wherein the mobile device holder includes an extension arm that can be pliably shaped into various configurations capable of supporting the weight of the mobile device holder;
shaping the extension arm into a configuration; and
supporting at least a portion of the weight of the mobile device holder with the extension arm in the configuration.

17. The method of claim 16, wherein supporting at least the portion of the weight of the mobile device holder with the extension arm in the configuration includes bending the extension arm around at least a portion of an object.

18. The method of claim 16, wherein supporting at least the portion of the weight of the mobile device holder with the extension arm in the configuration includes standing the mobile device holder on a surface.

19. The method of claim 16 further comprising securely holding the extension arm against a body portion of the mobile holder device.

20. A mobile device holder, comprising:
a body portion including:
a mobile device receiving area within an interior of the body portion;
a front surface defining a mobile device display window; and
a back surface opposite the front surface;
a first extension arm attached to the back surface of the body portion; and
a second extension arm attached to the back surface of the body portion, wherein:
the first extension arm and the second extension arm are rotatably mounted to the body portion; and
the first extension arm and the second extension arm can each be pliably shaped into various configurations such that first extension arm and the second extension are capable of supporting the weight of the mobile device holder.
